(19) United States
(12) Patent Application Publication
(10) Pub. No.: US 2016/0240708 A1
(43) Pub. Date: Aug. 18, 2016

(54) SOLAR CELL WITH A HETERO-JUNCTION STRUCTURE AND METHOD FOR MANUFACTURING THE SAME

(71) Applicant: NEO SOLAR POWER CORP., Hsinchu (TW)

(72) Inventor: Peng CHEN, Hsinchu (TW)

(21) Appl. No.: 14/672,912

(22) Filed: Mar. 30, 2015

(30) Foreign Application Priority Data
Feb. 13, 2015 (TW) 104105134

(51) Int. Cl. H01L 31/0376; H01L 31/20; H01L 31/18

(52) U.S. Cl. CPC H01L 31/03762; H01L 31/1884; H01L 31/20

(57) ABSTRACT

A solar cell with a hetero junction structure includes a substrate, a first buffer layer, a second buffer layer, a second n-type amorphous semiconductor layer, a second p-type amorphous semiconductor layer, a first transparent conductive oxide (TCO) layer and a second TCO layer. A method for manufacturing the aforesaid solar cell includes the steps of forming the first n-type and the first p-type amorphous semiconductor layers respectively on a first surface and a second surface of the substrate, dope-treating the first n-type and the first p-type amorphous semiconductor layers by a gas plasma, and forming a first and a second intrinsic amorphous semiconductor layers respectively on the first n-type and the first p-type amorphous semiconductor layers.

This application claims the benefit of Taiwan Patent Application Serial No. 104105134 filed on Feb. 13, 2015, the subject matter of which is incorporated herein by reference.

### BACKGROUND OF INVENTION

1. Field of the Invention

The invention relates to a solar cell with a hetero junction structure and a method for manufacturing the same, and more particularly to the solar cell with a hetero-junction structure and the accompanying manufacturing method that introduce a combination of an n-type amorphous semiconductor layer, a p-type amorphous semiconductor layer and an intrinsic amorphous semiconductor layer to act as a buffer layer.

2. Description of the Prior Art

Referring now to FIG. 1, a conventional solar cell with a hetero junction structure in the art is schematically shown. As shown, the conventional solar cell with a hetero junction structure PA100 includes a semiconductor substrate PA1, a first intrinsic amorphous semiconductor layer PA2, a second intrinsic amorphous semiconductor layer PA3, a second n-type amorphous semiconductor layer PA4, a second p-type amorphous semiconductor layer PA5, a first TCO layer PA6, a second TCO layer PA7, at least one first conductive line PA8 (one labeled in the figure), and at least one second conductive line PA9 (one labeled in the figure).

The semiconductor substrate PA1 doped as a first type semiconductor (for example, an n-type semiconductor) is typical a crystal silicon semiconductor substrate. The first intrinsic amorphous semiconductor layer PA2 and the second intrinsic amorphous semiconductor layer PA3 are respectively formed to opposing sides of the semiconductor substrate PAL

The second n-type amorphous semiconductor layer PA4 formed on top of the first intrinsic amorphous semiconductor layer PA2 is doped by the first type semiconductor. The second p-type amorphous semiconductor layer PA5 formed on top of the second intrinsic amorphous semiconductor layer PA3 is doped by a second type semiconductor (for example, a p-type semiconductor). In this conventional solar cell, by providing the corresponding intrinsic amorphous semiconductor layers topped by the corresponding amorphous semiconductor layers doped respectively by the first type semiconductor and the second type semiconductor to the opposing sides of the crystal silicon semiconductor substrate, a double-layered hetero junction layer can be formed to effectively enhance the photovoltaic conversion efficiency of the solar cell.

Nevertheless, in practice, for the first intrinsic amorphous semiconductor layer PA2 and the second intrinsic amorphous semiconductor layer PA3 usually contain dispersing defects, the movement of the electrons and the electron holes would be adversely affected. In order to resolve problems caused by these defects in the intrinsic amorphous semiconductor layers, a hydrogen plasma treatment (HPT) is applied to introduce high-concentrated hydrogen to combine the dangling bond and the hydrogen ion of the intrinsic amorphous silicon while in depositing the intrinsic layer, such that the in-layer defects can be reduced.

In addition, in some applications, the intrinsic layer is formed by doping slightly an n-type semiconductor or a p-type semiconductor, so that the overall resistance of the solar cell with a hetero junction structure can be reduced. However, though reduced doping might reduce the overall resistance, yet the density of interface state is increased as well.

### SUMMARY OF THE INVENTION

In view of the aforesaid prior art, the hetero junction structure is usually produced by forming the intrinsic layers and the amorphous semiconductor layers to opposing sides of the crystal silicon semiconductor substrate, in which the intrinsic layer is to passivate the dangling bonds of the substrate. Further for the body of the intrinsic layer contains less defects, so the hetero junction can be effectively formed, and the open-circuit voltage of the solar cell can be raised.

However, for the intrinsic layer is usually not doped by p-type or n-type semiconductors and thereby would have higher electric resistance. In addition, for the intrinsic layer carries less interface fixed electrons, the passivation of the field effect would be dim and further to influence the filling factor of the cell so as to limit the power of the solar cell with a hetero junction structure. To improve such a problem, the aforesaid light doping process is applied to reduce the resistance value so as to enhance the field effect. However, such a resort would lead to the increase of the density of interface defect state.

Accordingly, one embodiment of the present invention, a solar cell with a hetero junction structure and a manufacturing method thereof, in which light doping upon the p-type and n-type amorphous semiconductor layers is performed by a plasma treatment of a doping gas so as to reduce the density of interface defect state and the resistance value, but to enhance the passivation of the field effect.

In the present invention, the solar cell with a hetero junction structure includes a semiconductor substrate, a first buffer layer, a second buffer layer, a second n-type amorphous semiconductor layer, a second p-type amorphous semiconductor layer, a first TCO layer and a second TCO layer. The semiconductor substrate has a first surface and a second surface opposite to the first surface, and is doped by a first type semiconductor.

The first buffer layer formed on the first surface includes a first n-type amorphous semiconductor layer and an intrinsic amorphous semiconductor layer. The first n-type amorphous semiconductor layer directly formed on the first surface is doped by an n-type semiconductor with a dope concentration ranged from 1×10¹⁴ to 1×10¹⁶ atoms/cm³. The first intrinsic amorphous semiconductor layer is then formed on the first n-type amorphous semiconductor layer.

The second buffer layer formed on the second surface includes a first p-type amorphous semiconductor layer and a second intrinsic amorphous semiconductor layer. The first p-type amorphous semiconductor layer formed directly on the second surface is doped by a p-type semiconductor with a dope concentration ranged from 1×10¹⁴ to 1×10¹⁶ atoms/cm³. The second intrinsic amorphous semiconductor layer is then formed on the first p-type amorphous semiconductor layer.

The second n-type amorphous semiconductor layer formed on the first buffer layer is doped by a second type semiconductor. The second p-type amorphous semiconductor layer formed on the second buffer layer is doped by the first type semiconductor. The first TCO layer is formed on the second n-type amorphous semiconductor layer, and the second TCO layer is formed on the second p-type amorphous semiconductor layer.

In the present invention, the introduction of the doping treatment upon both the first n-type amorphous semiconductor layer of the first and the first p-type amorphous semiconductor layer of the second buffer layer and a doping gas plasma treatment upon both the first n-type amorphous semiconductor layer and the first p-type amorphous semiconductor layer can reduce substantially the overall electric resistance, enhance effectively the performance in field effect, and lower greatly the density of interface state.

In one embodiment of the present invention, the first n-type amorphous semiconductor layer and the first p-type amorphous semiconductor layer are formed of a material selected from the group consisting of amorphous silicon (a-Si), amorphous silicon nitride (a-Si₃N₄), amorphous silicon oxide (a-SiO₂) and amorphous aluminum oxide (a-Al₂O₃).

In one embodiment of the present invention, the first intrinsic amorphous semiconductor layer and the second intrinsic amorphous semiconductor layer are formed of a material selected from the group consisting of amorphous silicon (a-Si), amorphous silicon nitride (a-Si₃N₄), amorphous silicon oxide (a-SiO₂) and amorphous aluminum oxide (a-Al₂O₃).

In one embodiment of the present invention, the semiconductor substrate is a crystal silicon substrate.

In one embodiment of the present invention, the first type semiconductor is an n-type semiconductor.

In one embodiment of the present invention, a thickness of any of the first n-type amorphous semiconductor layer and the first p-type amorphous semiconductor layer is ranged from 0.1 nm to 10 nm.

In one embodiment of the present invention, a thickness of any of the first intrinsic amorphous semiconductor layer and the first intrinsic amorphous semiconductor layer is ranged from 1 nm to 10 nm.

In the present invention, the manufacturing method of the solar cell with a hetero junction structure includes the following steps: (a) providing a semiconductor substrate doped by a first type semiconductor; (b) forming a first n-type amorphous semiconductor layer of a first buffer layer on a first surface of the semiconductor substrate, wherein the first n-type amorphous semiconductor layer is doped by an n-type semiconductor with a dope concentration ranged from 1×10¹⁴ to 1×10¹⁶ atoms/cm³; (c) forming a first intrinsic amorphous semiconductor layer of the first buffer layer on the first n-type amorphous semiconductor layer; (d) forming a first p-type amorphous semiconductor layer of a second buffer layer on a second surface of the semiconductor substrate, wherein the first p-type amorphous semiconductor layer is doped by a p-type semiconductor with a dope concentration ranged from 1×10¹⁴ to 1×10¹⁶ atoms/cm³; (e) forming a second intrinsic amorphous semiconductor layer of the second buffer layer on the first p-type amorphous semiconductor layer; (f) forming a second n-type amorphous semiconductor layer on the first buffer layer; and (g) forming a second p-type amorphous semiconductor layer on the second buffer layer.

In one embodiment of the present invention, after performing the step (b), further including a step of: (b1) treating the first n-type amorphous semiconductor layer by a doping gas. Preferably, the doping gas includes at least one of a phosphine gas, an Arsine, a nitrogen and a hydrogen.

In one embodiment of the present invention, after performing the step (c), further including a step of: (c1) treating the first p-type amorphous semiconductor layer by a doping gas. Preferably, the doping gas includes at least one of a phosphine gas, an Arsine, a nitrogen and a hydrogen.

In one embodiment of the present invention, a step (h) of forming a first TCO layer and a second TCO layer on the first amorphous semiconductor layer and the second amorphous semiconductor layer respectively is performed after the step (g).

In one embodiment of the present invention, the step (h) is firstly to form the first TCO layer, and then to form the second TCO layer.

In one embodiment of the present invention, the step (h) is firstly to form the second TCO layer, and then to form the first TCO layer.

In one embodiment of the present invention, the step (h) is to form the first TCO layer and the second TCO layer simultaneously.

### BRIEF DESCRIPTION OF THE DRAWINGS

The present invention will now be specified with reference to its preferred embodiment illustrated in the drawings, in which:

FIG. 1 is a schematic view of a conventional hetero junction solar cell;

FIG. 2 is a schematic view of the preferred solar cell with a hetero junction structure in accordance with the present invention; and

FIG. 3A and FIG. 3B are together to show a flowchart of the preferred manufacturing method of the solar cell with a hetero junction structure in accordance with the present invention.

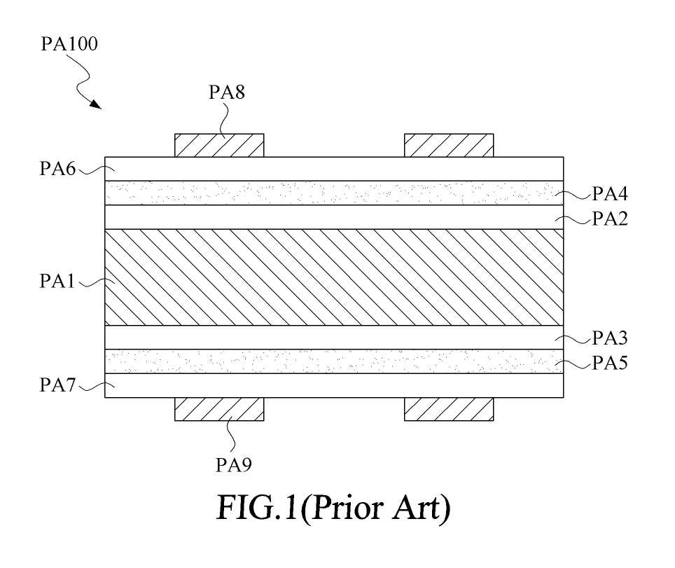

### DESCRIPTION OF THE PREFERRED EMBODIMENT

The invention disclosed herein is directed to a solar cell with a hetero junction structure and a manufacturing method thereof. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

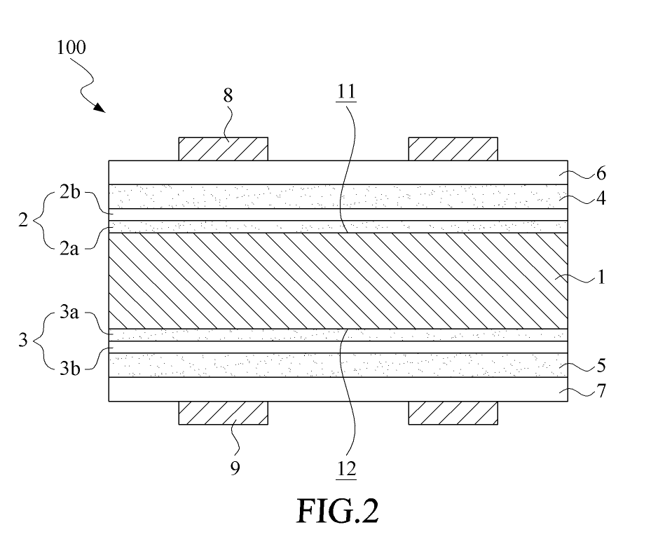

Referring now to FIG. 2, a schematic view of the preferred solar cell with a hetero junction structure in accordance with the present invention is shown. As shown, the solar cell with a hetero-junction structure 100 includes a semiconductor substrate 1, a first buffer layer 2, a second buffer layer 3, a second n-type amorphous semiconductor layer 4, a second p-type amorphous semiconductor layer 5, a first TCO layer 6, a second TCO layer 7, a plurality of first leads 8 (two shown in the figure) and a plurality of second leads 9 (two shown in the figure).

The semiconductor substrate 1 has a first surface 11 and a second surface 12 opposite to the first surface 11, and is doped by a first type semiconductor, in which the semiconductor substrate 1 can be a crystal silicon substrate, the first type semiconductor can be an n-type semiconductor or a p-type semiconductor. Preferably, in this embodiment, the first type semiconductor is an n-type semiconductor.

The first buffer layer 2 formed on the first surface 11 includes a first n-type amorphous semiconductor layer 2a and a first intrinsic amorphous semiconductor layer 2b. The first n-type amorphous semiconductor layer 2a directly formed on the first surface 11 has a lightly doped n-type semiconductor, produced by applying a doping gas plasma treatment to process the dangling bonds in the first n-type amorphous semiconductor layer 2a. In the present invention, the first n-type amorphous semiconductor layer 2a and the first intrinsic amorphous semiconductor layer 2b are formed of a material selected from the group consisting of amorphous silicon (a-Si), amorphous silicon nitride (a-Si₃N₄), amorphous silicon oxide (a-SiO₂) and amorphous aluminum oxide (a-Al₂O₃), a thickness of the first n-type amorphous semiconductor layer 2a is ranged from 0.1 nm to 10 nm, and a thickness of the first intrinsic amorphous semiconductor layer 2b is ranged from 1 nm to 10 nm. In particular, in this embodiment, the first n-type amorphous semiconductor layer 2a and the first intrinsic amorphous semiconductor layer 2b are both formed by the amorphous silicon (a-Si), the thickness of the first n-type amorphous semiconductor layer 2a is 2 nm, and the thickness of the first intrinsic amorphous semiconductor layer 2b is 3 nm.

In practice, the first n-type amorphous semiconductor layer 2a is deposited on the first surface 11 by a plasma enhanced chemical vapor deposition using PH₃ gas and SiH₄ gas. Through the flux and percentage control upon the PH₃ gas and the SiH₄ gas, the n-type semiconductor (P) can be deposited into the first n-type amorphous semiconductor layer 2a in a light doping manner. The dope concentration is ranged from ×10¹⁴ to 1×10¹⁶ atoms/cm³. Then, the doping gas plasma treatment is applied to modify the first n-type amorphous semiconductor layer 2a so as to deactivate the dangling bonds in the first n-type amorphous semiconductor layer 2a caused by the amorphous structure. Herein, the doping gas plasma treatment is a hydrogen plasma treatment, a PH₃ plasma treatment, a B₂H₆ plasma treatment, or a nitrogen plasma treatment. In this embodiment, the hydrogen plasma treatment is applied.

The first intrinsic amorphous semiconductor layer 2b is formed on top of the first n-type amorphous semiconductor layer 2a. Practically, the deposition of the first intrinsic amorphous semiconductor layer 2b on top of the first n-type amorphous semiconductor layer 2a is performed by applying a plasma enhanced chemical vapor deposition using H₂ gas and SiH₄ gas.

The second buffer layer 3 formed on the second surface 12 includes a first p-type amorphous semiconductor layer 3a and a second intrinsic amorphous semiconductor layer 3b. The first p-type amorphous semiconductor layer 3a directly formed on the second surface 12 has a lightly doped p-type semiconductor, produced by applying a doping gas plasma treatment to process the dangling bonds in the first p-type amorphous semiconductor layer 3a. In the present invention, the first p-type amorphous semiconductor layer 3a and the second intrinsic amorphous semiconductor layer 3b are formed of a material selected from the group consisting of amorphous silicon (a-Si), amorphous silicon nitride (a-Si₃N₄), amorphous silicon oxide (a-SiO₂) and amorphous aluminum oxide (a-Al₂O₃), a thickness of the first p-type amorphous semiconductor layer 3a is ranged from 0.1 nm to 10 nm, and a thickness of the second intrinsic amorphous semiconductor layer 3b is ranged from 1 nm to 10 nm. In particular, in this embodiment, the first p-type amorphous semiconductor layer 3a and the second intrinsic amorphous semiconductor layer 3b are both formed by the amorphous silicon (a-Si), the thickness of the first p-type amorphous semiconductor layer 3a is 2 nm, and the thickness of the second intrinsic amorphous semiconductor layer 3b is 3 nm.

In practice, the first p-type amorphous semiconductor layer 3a is deposited on the second surface 12 by a plasma enhanced chemical vapor deposition using B₂H₆ gas and SiH₄ gas. Through the flux and percentage control upon the B₂H₆ gas and the SiH₄ gas, the p-type semiconductor (B) can be deposited into the first p-type amorphous semiconductor layer 3a in a light doping manner. The dope concentration is ranged from 1×10¹⁴ to 1×10¹⁶ atoms/cm³. Then, the doping gas plasma treatment is applied to modify the first p-type amorphous semiconductor layer 3a so as to deactivate the dangling bonds in the first p-type amorphous semiconductor layer 3a caused by the amorphous structure. Herein, the doping gas plasma treatment is a hydrogen plasma treatment.

The second intrinsic amorphous semiconductor layer 3b is formed on top of the first p-type amorphous semiconductor layer 3a. Practically, the deposition of the second intrinsic amorphous semiconductor layer 3b on top of the first p-type amorphous semiconductor layer 3a is performed by applying a plasma enhanced chemical vapor deposition using H₂ gas and SiH₄ gas.

The second n-type amorphous semiconductor layer 4 formed on the first intrinsic amorphous semiconductor layer 2b of the first buffer layer 2. Practically, the second n-type amorphous semiconductor layer 4 is deposited on the first intrinsic amorphous semiconductor layer 2b by the plasma enhanced chemical vapor deposition using PH₃ gas and SiH₄ gas. The dope concentration of the n-type semiconductor of the second n-type amorphous semiconductor layer 4 is ranged from 1×10¹⁴ to 1×10¹⁶ atoms/cm³.

The second p-type amorphous semiconductor layer 5 formed on the second intrinsic amorphous semiconductor layer 3b of the second buffer layer 3. Practically, the second p-type amorphous semiconductor layer 5 is deposited on the second intrinsic amorphous semiconductor layer 3b by the plasma enhanced chemical vapor deposition using B₂H₆ gas and SiH₄ gas. The dope concentration of the p-type semiconductor of the second p-type amorphous semiconductor layer 5 is ranged from 1×10¹⁴ to ×10¹⁶ atoms/cm³.

The first TCO layer 6 is formed on the second n-type amorphous semiconductor layer 4. Practically, the first TCO layer 6 is deposited on the second n-type amorphous semiconductor layer 4 by the plasma enhanced chemical vapor deposition.

The second TCO layer 7 is formed on the second p-type amorphous semiconductor layer 5. Practically, the second TCO layer 7 is deposited on the second p-type amorphous semiconductor layer 5 by the plasma enhanced chemical vapor deposition. In the present invention, the first TCO layer 6 and the second TCO layer 7 can be made of, but not limited to, a transparent conductive metallic compound such as the ITO, the IWO, the ICO, the AZO or the ZnO.

The first lead 8 is disposed on the first TCO layer 6, and the second lead 9 is disposed on the second TCO layer 7, in which the first lead 8 and the second lead 9 can be made of a metal with a high electric conductivity, such as an Ni, an Ag or a Cu.

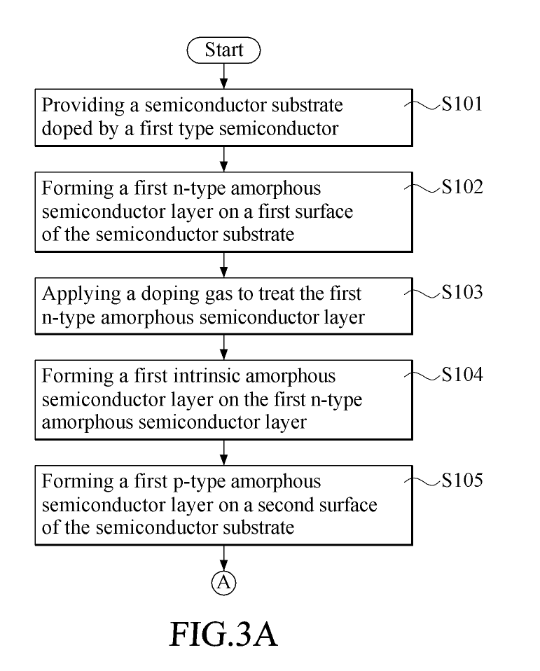

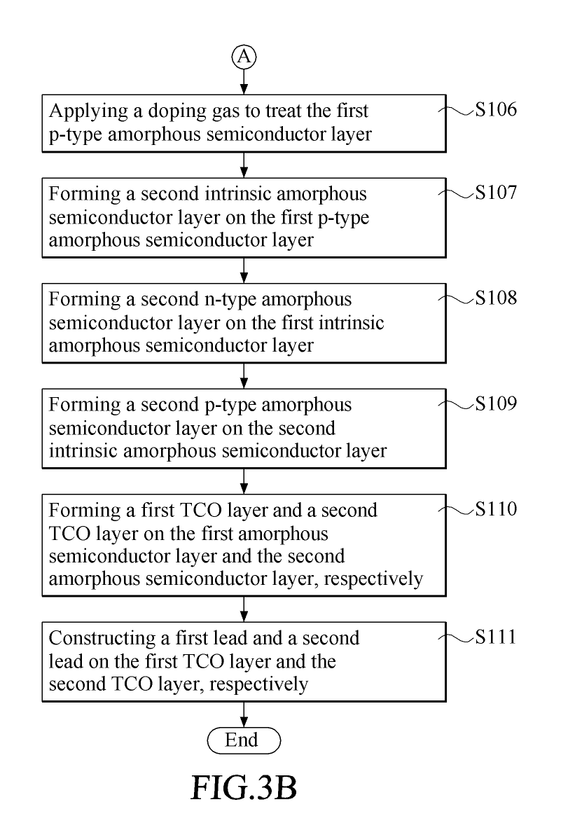

Refer now to FIG. 2, FIG. 3A and FIG. 3B, in which FIG. 3A and FIG. 3B are together to show a flowchart of the preferred manufacturing method of the solar cell with a hetero-junction structure in accordance with the present invention. As shown, the manufacturing method of the solar cell with a hetero junction structure 100 includes the following steps.

Step S101: Provide the semiconductor substrate 1 doped by the first type semiconductor.

Step S102: Form the first n-type amorphous semiconductor layer 2a on the first surface 11 of the semiconductor substrate 1, in which the first n-type amorphous semiconductor layer 2a is doped by the n-type semiconductor with a dope concentration ranged from 1×10¹⁴ to 1×10¹⁶ atoms/cm³.

Step S103: Apply the doping gas plasma treatment to treat the first n-type amorphous semiconductor layer 2a. Practically, the doping gas is introduced in a plasma manner to deactivate the dangling bonds of the first n-type amorphous semiconductor layer 2a.

Step S104: Form the first intrinsic amorphous semiconductor layer 2b on the first n-type amorphous semiconductor layer 2a.

Step S105: Form the first p-type amorphous semiconductor layer 3a on the second surface 12 of the semiconductor substrate 1, in which the first p-type amorphous semiconductor layer 3a is doped by the p-type semiconductor with a dope concentration ranged from 1×10¹⁴ to 1×10¹⁶ atoms/cm³.

Step S106: Apply the doping gas plasma treatment to treat the first p-type amorphous semiconductor layer 3a. Practically, the doping gas is introduced in a plasma manner to deactivate the dangling bonds of the first p-type amorphous semiconductor layer 3a.

Step S107: Form the second intrinsic amorphous semiconductor layer 3b on the first p-type amorphous semiconductor layer 3a.

Step S108: Form the second n-type amorphous semiconductor layer 4 on the first intrinsic amorphous semiconductor layer 2b.

Step S109: Form the second p-type amorphous semiconductor layer 5 on the second intrinsic amorphous semiconductor layer 3b.

Step S110: Form the first TCO layer 6 and the second TCO layer 7 on the second n-type amorphous semiconductor layer 4 and the second p-type amorphous semiconductor layer 5, respectively. In the present invention, the Step S110 can be performed by forming the first TCO layer 6 first, by forming the second TCO layer 7 first, or by forming the first TCO layer 6 and the second TCO layer 7 simultaneously.

Step S111: Construct the first lead 8 on the first TCO layer 6, and construct the second lead 9 on the second TCO layer 7.

In the present invention, the Step S102 and the Step S105 are exchangeable in order according to practical requirements. Also, the Step S104 and the Step S107 are exchangeable in order according to practical requirements. However, the step S103 and the step S104 need to be performed posterior to the step S102, and the step S106 and the step S107 need to be performed posterior to the step S105. In addition, the Step S108 and the Step S109 are exchangeable in order according to practical requirements. Nevertheless, practically, the order of the forming process is preferably to consider the working surface of the semiconductor substrate 1 and the equipments needed for the production. For example, it is noted that the steps S102, S104 and S108 are performed on the same side of the semiconductor substrate 1, and processes for the aforesaid steps are all the plasma enhanced chemical vapor depositions.

In summary, by compared to the prior art that uses the hydrogen plasma treatment to reduce the density of interface defect state of the intrinsic layer or reduce the resistance value by lightly doped intrinsic layer, the present invention utilizes the construction of the first n-type amorphous semiconductor layer and the first p-type amorphous semiconductor layer, slight dopants of the n-type semiconductor and the p-type semiconductor can be introduced to reduce the resistance value and to enhance the passivation of the field effect. Further, after the forming of the first n-type amorphous semiconductor layer and the first p-type amorphous semiconductor layer, the plasma enhanced chemical vapor deposition is further applied to deactivate the dangling bonds in the first n-type amorphous semiconductor layer and the first p-type amorphous semiconductor layer, so that the density of the interface defect state can be substantially reduced. Hence, by compared to the prior art, the present invention can use light doping upon the first n-type amorphous semiconductor layer and the first p-type amorphous semiconductor layer so as to reduce the overall electric resistance and enhance the passivation of the field effect. Further, for the first n-type amorphous semiconductor layer and the first p-type amorphous semiconductor layer are modified by the doping gas plasma treatment, so the density of the interface defect state in the first buffer layer and the second buffer layer can be substantially reduced, and thus the overall transformation efficiency of the solar cell with a hetero junction structure can be successfully improved.

While the present invention has been particularly shown and described with reference to a preferred embodiment, it will be understood by those skilled in the art that various changes in form and detail may be without departing from the spirit and scope of the present invention.

What is claimed is:

1. A solar cell with a hetero junction structure, comprising:
a semiconductor substrate, having a first surface and a second surface opposing to the first surface, doped by a first type semiconductor;
a first buffer layer, formed on the first surface, further including:
a first n-type amorphous semiconductor layer, formed on the first surface, doped by an n-type semiconductor with a dope concentration ranged from 1×10¹⁴ to 1×10¹⁶ atoms/cm³; and
a first intrinsic amorphous semiconductor layer, formed on the first n-type amorphous semiconductor layer;
a second buffer layer, formed on the second surface, further including:
a first p-type amorphous semiconductor layer, formed on the second surface, doped by a p-type semiconductor with a dope concentration ranged from 1×10¹⁴ to 1×10¹⁶ atoms/cm³; and
a second intrinsic amorphous semiconductor layer, formed on the first p-type amorphous semiconductor layer;
a second n-type amorphous semiconductor layer, formed on the first buffer layer;
a second p-type amorphous semiconductor layer, formed on the second buffer layer;
a first transparent conductive oxide (TCO) layer, formed on the second n-type amorphous semiconductor layer; and
a second transparent conductive oxide (TCO) layer, formed on the second p-type amorphous semiconductor layer.

2. The solar cell with a hetero-junction structure of claim 1, wherein the first n-type amorphous semiconductor layer and the first p-type amorphous semiconductor layer are formed of a material selected from the group consisting of amorphous silicon (a-Si), amorphous silicon nitride (a-Si₃N₄), amorphous silicon oxide (a-SiO₂) and amorphous aluminum oxide (a-Al₂O₃).

3. The solar cell with a hetero-junction structure of claim 1, wherein the first intrinsic amorphous semiconductor layer and the second intrinsic amorphous semiconductor layer are formed of a material selected from the group consisting of amorphous silicon (a-Si), amorphous silicon nitride (a-Si₃N₄), amorphous silicon oxide (a-SiO₂) and amorphous aluminum oxide (a-Al₂O₃).

4. The solar cell with a hetero-junction structure of claim 1, wherein the first type semiconductor is an n-type semiconductor.

5. The solar cell with a hetero-junction structure of claim 1, wherein a thickness of any of the first n-type amorphous semiconductor layer and the first p-type amorphous semiconductor layer is ranged from 0.1 nm to 10 nm.

6. The solar cell with a hetero junction structure of claim 1, wherein a thickness of any of the first intrinsic amorphous semiconductor layer and the first intrinsic amorphous semiconductor layer is ranged from 1 nm to 10 nm.

7. A method for manufacturing a solar cell with a hetero-junction structure, comprising the steps of:
(a) providing a semiconductor substrate doped by a first type semiconductor;
(b) forming a first n-type amorphous semiconductor layer of a first buffer layer on a first surface of the semiconductor substrate, wherein the first n-type amorphous semiconductor layer is doped by an n-type semiconductor with a dope concentration ranged from 1×10¹⁴ to 1×10¹⁶ atoms/cm³;
(c) forming a first intrinsic amorphous semiconductor layer of the first buffer layer on the first n-type amorphous semiconductor layer;
(d) forming a first p-type amorphous semiconductor layer of a second buffer layer on a second surface of the semiconductor substrate, wherein the first p-type amorphous semiconductor layer is doped by a p-type semiconductor with a dope concentration ranged from 1×10¹⁴ to 1×10¹⁶ atoms/cm³;
(e) forming a second intrinsic amorphous semiconductor layer of the second buffer layer on the first p-type amorphous semiconductor layer;
(f) forming a second n-type amorphous semiconductor layer on the first buffer layer;
(g) forming a second p-type amorphous semiconductor layer on the second buffer layer; and
(h) forming a first TCO layer and a second TCO layer on the first amorphous semiconductor layer and the second amorphous semiconductor layer, respectively.

8. The method for manufacturing a solar cell with a hetero junction structure of claim 7, after performing the step (b), further including a step of:
(b1) treating the first n-type amorphous semiconductor layer by a doping gas.

9. The method for manufacturing a solar cell with a hetero junction structure of claim 8, wherein the doping gas includes at least one of a phosphine gas, an Arsine, a nitrogen and a hydrogen.

10. The method for manufacturing a solar cell with a hetero junction structure of claim 7, after performing the step (c), further including a step of:
(c1) treating the first p-type amorphous semiconductor layer by a doping gas.

11. The method for manufacturing a solar cell with a hetero-junction structure of claim 10, wherein the doping gas includes at least one of a phosphine gas, an Arsine, a nitrogen and a hydrogen.

12. The method for manufacturing a solar cell with a hetero-junction structure of claim 7, wherein the step (h) is firstly to form the first TCO layer, and then to form the second TCO layer.

13. The method for manufacturing a solar cell with a hetero-junction structure of claim 7, wherein the step (h) is firstly to form the second TCO layer, and then to form the first TCO layer.

14. The method for manufacturing a solar cell with a hetero junction structure of claim 7, wherein the step (h) is to form the first TCO layer and the second TCO layer simultaneously.
